(19) United States
(12) Patent Application Publication
(10) Pub. No.: US 2015/0027527 A1
(43) Pub. Date: Jan. 29, 2015

(54) Solar Cell and Process for Producing a Solar Cell

(71) Applicants: Wilhelm Stein, Dresden (DE); Michael Grimm, Chemnitz (DE); Martin Plettig, Hohenstein-Ernstthal (DE); Giuseppe Citarella, Chemnitz (DE)

(72) Inventors: Wilhelm Stein, Dresden (DE); Michael Grimm, Chemnitz (DE); Martin Plettig, Hohenstein-Ernstthal (DE); Giuseppe Citarella, Chemnitz (DE)

(73) Assignee: Wilhelm Stein, Dresden (DE)

(21) Appl. No.: 14/362,092

(22) PCT Filed: Nov. 14, 2012
(86) PCT No.: PCT/IB2012/056412

§ 371 Date: Sep. 30, 2014

(30) Foreign Application Priority Data
Dec. 1, 2011 (DE) 10 2011 055 912.4

(51) Int. Cl. H01L 31/02

(52) U.S. Cl. CPC H01L 31/02008
USPC 136/256; 438/98

(57) ABSTRACT

A solar cell core is produced such that a charge separation and a charge transfer to an emitter and to a base located on a side of the solar cell that is opposite from the emitter are provided when there is incident light in a front side of the solar cell. An electrically conductive emitter-contact structure is produced in the form of contact fingers that are in direct electrical contact with the emitter. A solderable metallic emitter-terminal structure is produced in the form of conductor bars that are in direct electrical contact with the emitter-contact structures and transversely connect the contact fingers of the emitter-contact structure. The solderable metallic emitter-terminal structure is produced at least from nickel, a nickel alloy, tin and/or a tin alloy, and a solder or an electrically conductive strip arrangement covered with a solder is applied to this emitter-terminal structure.

This patent application is a national phase filing under section 371 of PCT/IB2012/056412, filed Nov. 12, 2012, which claims the priority of German patent application 10 2011 055 912.4, filed Dec. 1, 2011, each of which is incorporated herein by reference in its entirety.

### TECHNICAL FIELD

Embodiments of the invention relate to a solar cell and a process for producing a solar cell.

### BACKGROUND

Methods are established in the industrial manufacture of solar cells. For example, in accordance with this method, standard solar cells are manufactured in which the solar cell core has a base consisting of boron-doped crystalline silicon and a phosphor-doped emitter located on the front side of the solar cell. Contact is made with the emitter of this solar cell typically by means of contact fingers consisting of silver. The contact fingers are connected to one another by busbars. Connection tapes are soldered to these busbars for the external interconnection of the solar cell.

In the case of a standard solar cell, the contact fingers and the busbars are produced in accordance with the prior art by screenprinting from a silver paste in a common method step. In this case, contact is made with the base, which is typically located opposite the emitter on the rear side of the solar cell, by means of an aluminum layer, for example, wherein the aluminum layer forms the base contact structure. Since aluminum cannot be soldered, a solderable silver connection structure is applied to this base contact structure.

A problem associated with the manufacture of standard solar cells in accordance with previously known technologies consists in the high manufacturing costs thereof. The silver pastes used in the production of standard solar cells in this case represent a considerable proportion of the production costs. Therefore, attempts to reduce the production costs of solar cells, in particular by restricting the consumption of silver, can be found in the prior art.

German Patent Publication DE 10 2010 014 554 A1 discloses a solar cell in which a copper wire is used as busbar instead of a silver line, which copper wire is galvanized onto the contact fingers. One disadvantage with this solar cell and the associated production method is the requirement for special galvanization installations suitable for the method. In addition, when using copper there is the risk of this copper diffusing into the silicon of the solar cell. In order to prevent this, very effective barriers are required between the silicon and the copper. A further problem consists in the connection of the copper wires acting as busbars to the solar cell only at the small regions of overlap with the contact fingers. Owing to the small contact areas, the reliability of such solar cells is questionable.

In addition, German Patent Publication DE 10 2009 016 268 A1 discloses backside contact solar cells, for example, so-called interdigitated backside contact cells (IBC), in which contact is made with both the base and the emitter on the solar cell backside, wherein multilayered thin-film metal coatings are used instead of the known thick-film silver layers. One disadvantage with these solar cells consists in that their production is very complex and is associated with correspondingly high costs. The high costs of the method result, for example, from the relatively filigree backside structures, in which it is necessary to ensure separation of n- and p-regions and which can therefore only be realized with a greater complexity than is involved in the production of standard solar cells.

### SUMMARY OF THE INVENTION

Embodiments of the present invention relate to a method for producing a solar cell. A solar cell core is produced, in which, in the event of the incidence of light into a front side of the solar cell, charge separation and charge transfer to an emitter and to a base which is located on a side of the solar cell opposite the emitter are provided. An electrically conductive emitter contact structure is produced in the form of contact fingers, which are in direct electrical contact with the emitter. A solderable metallic emitter connection structure is produced in the form of busbars, which are in direct electrical contact with the emitter contact structure and cross-connect the contact fingers of the emitter contact structure. Contact is made with the emitter and the base on opposite sides of the solar cell.

Further embodiments of the invention relate to a solar cell comprising a solar cell core, in which, in the event of the incidence of light into a front side of the solar cell, charge separation and charge transfer to an emitter and to a base located on a side of the solar cell opposite the emitter are provided. An electrically conductive emitter contact structure is in direct electrical contact with the emitter A solderable metallic emitter connection structure is in direct electrical contact with the emitter contact structure. Contact is made with the emitter and the base on opposite sides of the solar cell.

A method of the generic type mentioned at the outset in which the solderable metallic emitter connection structure is produced at least from nickel, a nickel alloy, tin and/or a tin alloy, and a solder or an electrically conductive tape arrangement covered with a solder is applied to this emitter connection structure.

The method according to the invention differs from previously conventional standard solar cell production methods in which the emitter contact structure and the emitter connection structure are produced on the front side of the solar cell simultaneously in one method step in that the emitter contact structure and the emitter connection structure are now produced successively in different method steps, and the emitter connection structure is not formed from the very highly conductive silver which is established in standard solar cells. Instead, a material with, as is known, relatively poor conductivity, such as nickel or tin or an alloy of nickel or tin, is used in accordance with the invention to form the emitter connection structure. This material consists primarily either of nickel or tin, but can also be a nickel-tin alloy. In principle, other alloys of nickel and/or tin, for example, with vanadium, can also be used. The emitter connection structure does not need to be formed exclusively from a layer containing nickel, a nickel alloy, tin and/or a tin alloy, however. Thus, in accordance with the invention, additional layers such as, for example, an adhesion-promoting layer or a top layer can also be applied below or above the nickel-containing and/or tin-containing layer onto the solar cell.

Therefore, the present invention takes a quite unconventional approach to solar cell contact-making. In this case, expensive materials such as silver for the production of the emitter connection structure are explicitly dispensed with and the focus is on materials with much poorer electrical conductivity such as nickel, tin or an alloy of at least one of these materials. The electrical conductivity of this material is readily sufficient, however, to make electrical contact in a suitable manner with the emitter contact structure. Furthermore, materials such as nickel, tin and/or an alloy of these materials are very easily solderable, with the result that a solder or an electrically conductive tape arrangement covered with a solder can very readily be applied to an emitter connection structure produced from these materials in order to make contact with the solar cell. In end effect, with the method according to the invention, it is possible to produce a solar cell at much lower cost than in the prior art since, in accordance with the invention, the use of expensive materials such as silver for the production of the emitter connection structure is dispensed with. By virtue of the procedure according to the invention, in which firstly very good electrical contact is made by means of the emitter contact structure and secondly very good solderability is provided by means of the emitter connection structure, in addition solar cells of high quality can be produced.

A further advantage of the method according to the invention in comparison with solar cell standard technologies in which silver busbars are used as emitter connection structures consists in that the emitter connection structure materials proposed according to the invention do not negatively influence the silicon surface. In the case of conventional solar cells, there is instead the effect that the silver busbars provided for the soldering pass through the silicon nitride provided on the solar cell as far as the silicon surface. This reduces the efficiency of the solar cell. Attempts have been made in the prior art to avoid this by virtue of the contact fingers being pressed onto the solar cells and then a firing step being performed, whereupon the silver busbars are applied and then the silver busbars are merely dried, with the result that penetration of the silver down to the silicon core of the solar cell can be prevented. Such an effect does not pose a threat in particular when the emitter connection structure materials proposed according to the invention are sputtered, for example.

As already mentioned above, the solderable metallic emitter connection structure is solderable in the same way as a conventional emitter connection structure formed from silver, for example. As a result, a solar cell which has been produced using the method according to the invention can be further-processed in a standard production method without considerable modifications to the production. The external interconnection of the solar cell to other solar cells or external connection poles of solar modules can be performed without any modifications in terms of the method sequence. In the method according to the invention, a tin-containing solder and an electrically conductive tape arrangement can be applied to the emitter connection structure, for example. The electrically conductive tape arrangement can consist of two braided copper tapes, for example, which are soldered onto two busbars over the entire area. In this example, the tape arrangement comprising two copper tapes takes on the function of current collection and current discharge from the solar cell surface.

In other possible exemplary embodiments of the method according to the invention, the current transfer in the region of the emitter connection structure cannot take place via a conductive tape arrangement, but directly via a solder with a sufficiently large cross section, which solder can discharge the current generated in the solar cell. The emitter connection structure itself only needs to transfer the current perpendicularly from the emitter contact structure to the solder or the electrically conductive tape arrangement covered with solder. Lateral current transfer over relatively long distances is not provided in the emitter connection structure, on the other hand.

The term used in accordance with the invention “solar cell core” should be understood as having different breadth in meaning, depending on the present solar cell type. In the case of a standard solar cell, the typically n-conducting crystalline core of the solar cell which forms the base, the emitter layer with high n conductivity which is formed by diffusion of phosphor into the solar cell core on the front side of the solar cell and a backside layer with high levels of p-doping produced by reaction with aluminum belong to the solar cell core. The silicon nitride antireflection layer provided on the front side is used to minimize optical reflection and is no longer part of the solar cell core.

In another exemplary embodiment, the solar cell produced using the method according to the invention can be a so-called heterojunction solar cell, which is produced using a p-conducting starting wafer. The solar cell core of the heterojunction solar cell is formed, for example, by deposition of an undoped, i.e., intrinsic, semiconductor layer, an n-conducting semiconductor layer and a transparent and conductive surface layer. The transparent conductive surface layer consists of indium tin oxide, for example. Firstly, it takes on the function of the antireflective coating and secondly it also has electrical functions, such as the formation of the external electrical contact of the solar cell core.

An area which is as large as possible for the incidence of light is desired on the front side of the solar cell. Correspondingly, the emitter connection structure should cover and shadow as small an area as possible on the solar cell front side. Therefore, it is favorable to design the emitter connection structure to be as narrow as possible on the solar cell front side. Therefore, for good electrical conductivity, the entire emitter connection structure needs to be strengthened on the solar cell front side with the solder or the electrically conductive tape arrangement covered with solder. In the case of solar cells in which the emitter is located on the backside, a reduction in the connection structure area is not required or desirable in any case, however. The emitter connection structure can generally be applied over a large area to the backside of the solar cell, in which case only covering of a subarea of the emitter connection structure with solder or an electrically conductive tape arrangement covered with a solder can be provided.

In one configuration of the method according to the invention, the method furthermore has the following method steps: producing a base contact structure, which is in direct electrical contact with the base; producing a solderable metallic base connection structure, which is in direct electrical contact with the base contact structure, at least from nickel, a nickel alloy, tin and/or a tin alloy; and applying a solder or an electrically conductive tape arrangement covered with a solder to the base connection structure.

In this embodiment of the method according to the invention, the base connection structure is produced using a method which is similar to the production method according to the invention for the emitter connection structure. In this case, the emitter and the base are located on opposite sides of the solar cell. The requirements made of the emitter connection structure and the base connection structure result to a large extent from the solderability, from the material used for the external connection and from the requirements made of the solar cell as a whole.

The respectively provided connection structure is intended to shadow as small an area as possible on the front side of a solar cell irrespective of whether the latter is a solar cell in which the emitter connection structure or the base connection structure is located on the solar cell front side. As a result, it is also in this case expedient, when the base connection structure is located on the solar cell front side, for the structural sizes of said base connection structure to be as small as possible and for a solder or an electrically conductive tape arrangement covered with a solder to be provided on the entire base connection structure in order to realize good electrical conductivity. Such a covering of the base connection structure over the entire area is not absolutely necessary on the solar cell backside.

Depending on the layer sequence adjacent to the emitter connection structure or to the base connection structure, certain requirements can be placed on the respective contact structure. Thus, for example, a barrier effect with respect to copper, whose diffusion into the solar cell core generally needs to be prevented, is required. If the neighboring layers of the respective connection structure enable diffusion of copper into the solar cell core, the corresponding contact structure itself needs to act as diffusion barrier for copper. If the respective contact structure is located on other layers, however, such as on a silicon nitride antireflection layer which acts as diffusion barrier for copper, for example, the corresponding connection structure itself does not need to have a diffusion barrier effect with respect to copper.

In a preferred development of the method according to the invention, the emitter connection structure and/or the base connection structure is/are produced with a layer thickness of below 5 μm. In the case of a standard solar cell, emitter or base connection structures consisting of silver with a layer thickness of approximately 20 μm are often used. Such a large silver layer thickness is required in this case because solder and silver are easily dissolvable in one another and it is intended to prevent the contact structure consisting of silver from dissolving completely in order not to damage the solar cell core. In the mentioned exemplary embodiment of the method according to the invention, the emitter and/or base connection structure is/are preferably produced so as to be markedly thinner and with a layer thickness of below 5 μm, on the other hand. This is possible by virtue of the fact that nickel has low solubility in the solder applied to the emitter and/or base connection structure and only a few nanometers of a connection structure consisting of nickel are dissolved when soldering in the solder. This results firstly in a much lower consumption of materials than in conventional technologies. Secondly, for the application of such thin layers, methods which until now have not been suitable for efficiency reasons owing to the required thick layer thickness, such as sputtering methods, for example, now also come into consideration.

For reasons of further cost minimization, it is favorable to select the layer thicknesses to be as small as possible. Therefore, in accordance with one development of the method according to the invention, the emitter connection structure and/or the base connection structure is/are preferably produced with a layer thickness of between 50 nm and 500 nm. Depending on the type of solar cell, layer thicknesses of between 50 nm and 500 nm are sufficient for the functions of the connection structure in the production method for the emitter connection structure and/or the base connection structure. In the case of layer production methods which produce dense layers with few faults, generally relatively thin layer thicknesses are sufficient for producing the respective connection structure. In the case of layer production methods which produce layers of relatively low quality, on the other hand, slightly higher layer thicknesses are required.

Particularly preferably, in accordance with a further option of the method according to the invention, the emitter connection structure and/or the base connection structure is/are produced with a layer thickness of between 100 nm and 150 nm. These layer thicknesses have proven to be optimum for the practical implementation of the method according to the invention since they can be produced particularly efficiently and therefore result in low production costs for the solar cell, and furthermore allow very good electrical contact to be made with the emitter and/or base contact structure and in addition are very easily solderable.

In an advantageous variant of the method according to the invention, the emitter contact structure and/or the base contact structure is/are produced from a metal paste and/or from an electrolytic bath. Thick metal layers can be produced inexpensively and quickly from metal pastes. In addition, metal pastes can contain etching ingredients, with the result that, for example, during heat treatment of the metal paste for producing a metal, at the same time local etching and opening of an antireflection layer is possible. Another inexpensive method for producing thick metal layers or for increasing the thickness of thin seed layers is the production from an electrolytic bath. Metal ions which are moved in the direction of the contact structure by electrical or electrochemical potentials and deposited there are located in the electrolytic bath. The electrolytic material deposition can be used to harden or reinforce contact structures produced in another way.

Preferably, the emitter contact structure and/or the base contact structure is/are formed with a layer thickness of between 5 μm and 50 μm. These large layer thicknesses have proven favorable for fulfilling the tasks of the emitter and/or base contact structures in terms of method and design. Depending on the electrical resistivity, the emitter and/or base contact structures require a minimum line cross section to achieve the required low line resistances of the contact structures. Furthermore, the required layer thickness of the contact structures is also dependent on the method used for producing the emitter and/or base contact structures. For example, the production of metal layers from metal pastes is a thick-film method, which functions without faults only in the case of relatively large layer thicknesses. If the contact structures are produced from a material which has a lower resistivity than contact structures produced from metal pastes or if the contact structures are allowed to occupy a larger area on the backside of the solar cell, layer thicknesses of 5 μm or even smaller are also sufficiently large.

In a particularly suitable variant of the method according to the invention, the emitter contact structure is produced in the form of contact fingers from a silver paste. The production of emitter contact structures from silver pastes on the front side of solar cells is established in the industrial manufacture of solar cells. In the methods which are widespread in the industry, however, not only the contact fingers but also the busbars connected electrically to the contact fingers are produced from the silver paste. In order to produce the relatively wide busbars, a lot of silver is required in the prior art, which amounts to a considerable portion of the total costs of the solar cell. With the method according to the invention, the quantity of silver used in the production can be considerably reduced by virtue of the fact that in particular these busbars, i.e., the emitter connection structure, are not manufactured from silver, as a result of which the method according to the invention demonstrates its economic advantages. Silver contact fingers are typical for the solar cell front side, but it is also possible for solar cells with contact fingers to be produced from silver on the backside.

In a further embodiment of the method according to the invention, the emitter connection structure and/or the base connection structure is/are produced by locally performed layer deposition. In order to form connection structures on a subarea of the solar cell, there is in principle the possibility of deposition of a layer over the entire area, which is subsequently structured, or the possibility of locally performed layer deposition. Preferably, the locally performed layer deposition is used since this is simpler and less expensive. Furthermore, locally performed layer depositions are also sufficiently accurate for the relatively simple emitter and/or base connection structures. There are various possibilities for local layer depositions, for example, local inkjet printing with metal inks.

The deposition of the emitter connection structure and/or the base connection structure using a shadow mask by means of a physical vacuum deposition method has proven to be a particularly suitable variant embodiment of the method according to the invention. High-quality metal layers which are characterized by a high density and good conductivity are produced using physical vacuum deposition methods, such as sputtering, for example. Furthermore, in the case of physical vacuum deposition methods, typically a directional coating is performed, with the result that the desired structures can be produced sufficiently sharply using shadow masks. In principle, however, other deposition methods are also possible, for example, chemical gas phase depositions, laser-assisted gas phase depositions or screenprinting of metal pastes, for the production of emitter and/or base connection structures.

In an advantageous development of the method according to the invention, the emitter connection structure and the base connection structure are produced simultaneously in one method step. By virtue of simultaneously performing these two method steps, quick and inexpensive manufacture is achieved. In practice, the simultaneous production is performed by simultaneous operation of two sputter sources on the front side and backside of the solar cell, for example.

In accordance with a favorable configuration of the method according to the invention, the emitter contact structure and/or the base contact structure is/are produced in at least one method step initially by means of screenprinting of a metal paste, and the emitter connection structure and/or the base connection structure is/are produced in a subsequent method step. This method variant is particularly suitable for the production of standard solar cells in a manner modified in comparison with the prior art. In this case, an aluminum paste is printed first over a large area on the backside of the solar cell. Then, silver contact fingers are produced on the solar cell front side by screenprinting. The busbars which form the emitter connection structure or the base connection structure, on the other hand, are not screenprinted onto the front side of the solar cell. Then, the solar cell is fired in order to convert the screenprinted pastes into metal layers. On the backside of the solar cell, the aluminum reacts with the silicon in the process, with the result that a backside layer with a high level of doping which is in good electrical contact with the aluminum backside layer is formed. The fingers are burnt into the antireflection layer on the front side of the solar cell after the firing step and make contact with the emitter on the solar cell front side. Then, in this method variant according to the invention, the connection structures are produced on the front side and on the backside of the solar cell, for example, by means of sputtering of nickel. The sputtering preferably takes place using a sputtering mask on the front side of the solar cell. The backside of the solar cell, on the other hand, is preferably coated over a large area since, as a result, the complexity involved in the production and cleaning of a sputtering mask is no longer required on the backside. After the firing step, typically a final measurement of the produced solar cell takes place. In the method according to the invention, it may be necessary for the final measurement to be modified since peak measurement peaks could damage the thin nickel layers produced by sputtering.

In another option of the method according to the invention, said method is implemented in such a way that the emitter connection structure and/or the base connection structure is/are produced first in at least one method step, and the emitter contact structure and/or the base contact structure is/are produced in a subsequent method step. In this method variant, first the emitter connection structure and/or the base connection structure is/are applied to the solar cell core or to an antireflection layer provided thereon. The emitter contact structure and/or the base contact structure is/are produced only later, with the result that the contact structure in the region of the connection structure does not come into direct contact with the solar cell core. In the region of the busbars on the front side of the solar cells, there is also no contact required between the contact structure and the solar cell core. Instead, the contact between the contact structure and the solar cell core is rather disadvantageous than desirable primarily in the case of flat doping profiles. The described method variant can be used with various technologies. For example, in the case of a standard solar cell, such a method variant prevents the silver contact fingers from being burnt during firing of the silver paste in the region of the busbars by the antireflection layer.

In another exemplary embodiment, the above-described method variant can be used in the production of a heterojunction solar cell. The heterojunction solar cell has temperature-sensitive, thin layers, which define temperature upper limits for the production method. Correspondingly, the production method of heterojunction solar cells differs considerably from the production method for standard solar cells. Such a difference consists in the deposition of a transparent, electrically conductive oxide as antireflection layer instead of a dielectric antireflection layer. The transparent, electrically conductive oxide is used as electrical conductor, with the result that the firing step for the silver paste, in which the silver paste is burnt into the dielectric antireflection layer, can be dispensed with. In the production method of heterojunction solar cells, it has also proven successful to produce the emitter connection structure and/or the base connection structure prior to the emitter contact structure and/or the base contact structure.

In a typical development of the method according to the invention, the emitter contact structure and/or the base contact structure is/are screenprinted with a metal-polymer paste, and then a temperature treatment at temperatures below 300° C. is performed in order to convert the metal-polymer paste into at least one metal layer. When producing heterojunction solar cells, the high temperatures of, for example, 850° C. which are set during firing of silver paste during the production of standard solar cells are impermissible. The permitted temperatures are in this case much lower, for example, below 350° C. A tested variant for producing metal structures at the permitted low temperatures is the screenprinting of structures using metal-polymer pastes, which can be converted into conductive metal structures by temperature treatment below 300° C. These metal-polymer pastes, such as silver-polymer pastes, for example, are expensive products, however, with the result that there is considerable interest in minimizing the requirement of metal-polymer pastes. With the mentioned embodiment of the method according to the invention, the emitter connection structure and/or the base connection structure is/are produced without the use of metal-polymer pastes, with the result that only a fraction of the quantity of metal-polymer paste is used in comparison with a method in which the connection structures are also produced from a metal-polymer paste.

In a preferred variant of the method according to the invention, in at least one method step, the solder is applied to the emitter connection structure and/or the base connection structure with a layer thickness of at least 20 μm or a copper tape arrangement covered with solder is soldered onto the emitter connection structure and/or the base connection structure. In this way, line cross sections are produced on the connection structures which are large enough to conduct the current generated in the solar cell. Particularly preferably, in this case a copper tape arrangement is soldered on, i.e., each busbar is reinforced by a copper tape. The copper tape can be a solid copper tape. However, it may also be copper braiding which is mechanically softer and results in less mechanical loading on the solar cell. The connection structures can also be reinforced in another way, however, for example, a solder with a large layer thickness can be applied to the connection structures or the connection structure can be galvanically reinforced.

The object of the invention is furthermore achieved by a solar cell of the generic type in which the solderable metallic emitter connection structure is formed at least from nickel, a nickel alloy, tin and/or a tin alloy, wherein a solder or an electrically conductive tape arrangement covered with a solder is provided on the solderable metallic emitter connection structure.

In the case of the solar cell according to the invention, the front side connection structure of the solar cell is not formed from silver, as is conventional in the prior art, but instead from nickel, a nickel alloy, tin and/or a tin alloy. These materials are known for the fact that they have a much lower electrical conductivity than silver. As a result of this, such materials as nickel or tin or alloys thereof have previously not been taken into consideration at all for the formation of connection structures on solar cells. However, materials such as nickel, tin and alloys thereof are characterized by the fact that they are very easily solderable. Therefore, the solder applied to the emitter connection structure according to the invention or the tape arrangement covered with the solder can be soldered very easily to the emitter connection structure formed from nickel, tin or a nickel and/or tin alloy. In addition, the electrical conductivity of the emitter connection structure formed from nickel, tin or alloys thereof is quite sufficient for producing a suitable electrical contact between the emitter contact structure and the emitter connection structure. It is thus possible according to the invention to replace the busbars used as the emitter connection structure in the prior art, which generally consist of silver to over 90% and are therefore expensive, with substantially less expensive materials and therefore to save enormous costs in the production of solar cells.

In the case of a standard solar cell, the emitter is located on the solar cell front side, which is intended for exposure to sunlight, with the result that, with this type of solar cell, the emitter connection structure is intended to be understood as front side connection structure. In other types of solar cells, the emitter connection structure can also be provided on the backside of the solar cell, wherein the base connection in solar cells according to the invention is then located on the opposite front side. In the case where the emitter connection structure is provided on the backside of the solar cell, in one embodiment said emitter connection structure can be arranged opposite the front side connection structures in order to compensate for mechanical forces from the front side. In another exemplary embodiment, however, the emitter connection structure can also be formed over a large area or virtually over the entire area, for example, in order to achieve simplified production. In any case, a solder or an electrically conductive tape arrangement covered with a solder is provided on the solderable metallic emitter connection structure. The solder or the electrically conductive tape arrangement forms a substantial part of the line cross section on the emitter connection structure, which line cross section is required for the transfer of the photocurrent generated.

In an advantageous development of the solar cell according to the invention, a base contact structure is provided in direct electrical contact with the base, and a solderable metallic base connection structure is provided in direct electrical contact with the base contact structure, which base connection structure is formed at least from nickel, a nickel alloy, tin and/or a tin alloy, wherein a solder or an electrically conductive tape arrangement covered with a solder is provided on the solderable metallic base connection structure. In this development, not only the emitter contact structure on one side of the solar cell, but also the base contact structure on the other side of the solar cell is formed from nickel, a nickel alloy, tin and/or a tin alloy. In this way, silver is not required for any of the two connection structures, and a particularly great saving is made in comparison with connection structures formed from silver.

In a preferred development of the solar cell according to the invention, the emitter connection structure and/or the base connection structure has/have a layer thickness of below 5 μm. The emitter connection structure and/or the base connection structure does/do not primarily have the task of an electrical conductor, but is/are used substantially to form a suitable basis for the application of the solder or the electrically conductive tape arrangement covered with the solder. In order to fulfill this task, even small layer thicknesses of 5 μm or considerably less than 5 μm are sufficient. The required layer thickness is dependent, inter alia, on the production method which is used for forming the respective connection structure. In production methods which produce layers of lower quality, relatively large layer thicknesses are required, and in other production methods which produce dense layers, substantially thinner layers are already sufficient for forming suitable emitter and/or base connection structures. Furthermore, the required layer thickness is determined by the solubility of the material of the connection structure in the solder. The connection structure generally needs to be thick enough to avoid complete dissolving of the connection structure in the solder or in the electrically conductive tape arrangement covered with solder.

In advantageous configurations of the solar cell according to the invention, the emitter connection structure and/or the base connection structure has/have a layer thickness of between 50 nm and 500 nm. Particularly preferably, the emitter connection structure and/or the base connection structure has/have a layer thickness of between 100 nm and 150 nm. With these layer thicknesses, fully functional solar cells are produced, wherein the production costs for the connection structures are also low.

In a further embodiment of the solar cell according to the invention, the emitter connection structure and/or the base connection structure is/are formed from a metal paste and/or an electrolytically deposited material. The production of an emitter connection structure from a silver paste is a production method which is simple and established in the industry. However, one problem here consists in the high cost of silver, which in addition is ever increasing. However, not only silver pastes can be used as metal pastes; the use of aluminum pastes is also possible in the case of p-doped emitters. Furthermore, in different types of solar cells, other metal pastes, such as copper pastes, for example, can also be used. The emitter connection structure does not necessarily need to be formed from a metal paste, however; other production methods such as electrolytic deposition, for example, are also practicable.

In a preferred development of the solar cell according to the invention, the emitter connection structure and/or the base connection structure has/have a layer thickness of between 5 μm and 20 μm. The required layer thickness for the respective connection structure results from the required line cross section and the permissible line width. Narrow lines are necessary on the front side of the solar cell in order to shadow solar cell area as little as possible. In the case of narrow lines, a correspondingly larger layer thickness is used for realizing the required cross section. It is generally not necessary on the backside of the solar cell for the lines to be as narrow as are formed on the solar cell front side. In the case of relatively large line widths, therefore, smaller layer thicknesses are sufficient for producing sufficiently low line resistances.

It is particularly favorable if, in one exemplary embodiment of the solar cell according to the invention, the emitter connection structure and/or the base connection structure has/have contact fingers formed from a silver paste. Connection structures in the form of contact fingers are easily controllable and are therefore the preferred structures in the industry. By producing the contact fingers in the conventional manner from silver paste, the solar cell according to the invention can be produced on production lines with only minor modifications. As a result, there are only low resistances in the case of modification of production lines for producing the solar cell according to the invention.

According to one possible variant of the solar cell according to the invention, the emitter contact structure is provided between the solar cell core and the emitter connection structure and/or the base contact structure is provided between the solar cell core and the base connection structure. In this development, direct electrical contact is produced between the solar cell core and the connection structure via the contact structure. This design corresponds to the design which is conventional in standard solar cells.

In a preferred alternative development of the solar cell according to the invention, the emitter connection structure is provided between the solar cell core and the emitter contact structure and/or the base connection structure is provided between the solar cell core and the base contact structure. In this development, the area beneath the connection structures is not used, or is only used in restricted form, for making contact with the solar cell core by means of the contact structure. This area is also not required for making contact with the solar cell core; instead, less damage to the solar cell core is effected in the region of the connection structures and improved diffusion barriers, for example, with respect to the diffusion of copper, are produced.

### BRIEF DESCRIPTION OF THE DRAWINGS

Preferred embodiments of the present invention and the design, function and advantages thereof will be explained in more detail below with reference to figures, in which

FIG. 1 shows, schematically, an embodiment of a solar cell according to the invention in cross section;

FIG. 2 shows, schematically, a view of a front side of a solar cell according to the invention in a plan view;

FIG. 3 shows, schematically, a view of a backside of a solar cell according to the invention in a plan view;

FIG. 4 shows, schematically, an alternative embodiment of a solar cell according to the invention in cross section;

FIG. 5 shows, schematically, an alternative embodiment of a solar cell according to the invention in a plan view of the front side; and

FIG. 6 shows, schematically, an alternative embodiment of a solar cell according to the invention in a plan view of the backside.

### DETAILED DESCRIPTION OF ILLUSTRATIVE EMBODIMENTS

FIG. 1 shows, schematically, an exemplary embodiment of a solar cell 1 according to the invention in cross section. The solar cell 1 has a solar cell core 2, which has an emitter 3 and a base 4 on opposite sides of the solar cell core 2. In the event of the incidence of light into the solar cell 1, charge separation and charge transfer to the emitter 3 and to the base 4, which is located on that side of the solar cell 1 which is opposite the emitter 3, take place. The solar cell core 2 can have, in addition to the layers illustrated in FIG. 1, further layers, such as an undoped layer between the emitter 3 and the base 4 or conductive layers on one of the two surfaces of the solar cell core 2, for example.

The emitter 3 is in direct electrical contact with an electrically conductive emitter contact structure 5. Furthermore, an emitter connection structure 6 is provided on the emitter contact structure 5, which emitter connection structure cross-connects the individual webs of the emitter contact structure 5. By virtue of the direct electrical contact, a current can flow in the direction of the solar cell surface out of the solar cell core 2 into the emitter contact structure 5 as far as into the emitter connection structure 6. The term direct electrical contact also includes cases where the solar cell core 2 has further layers (not illustrated here), such as transparent conductive oxides, for example.

In the exemplary embodiment illustrated in FIG. 1, the emitter contact structure 5 is on the front side 9 of the solar cell 1, which is intended to be irradiated with light. The emitter contact structure 5 in the embodiment illustrated comprises narrow lines or fingers consisting of silver, which are produced from a silver paste. In the exemplary embodiment illustrated of the solar cell 1 according to the invention, only the emitter contact structure 5 is formed from silver, whereas the emitter connection structure 6 is formed from a thin nickel layer. In other embodiments of the present invention which are not shown, the emitter connection structure 6 can also be formed from tin, a nickel alloy or a tin alloy.

In the exemplary embodiment illustrated in FIG. 1, the emitter connection structure 6 comprises three busbars. The number of busbars illustrated has no further significance, however. In practice, any number of busbars is conceivable for forming the emitter connection structure 6. In the solar cell 1 according to the invention, a solder or an electrically conductive tape arrangement 11 covered with a solder is provided on the emitter connection structure 6, which consists of nickel in this example. A large proportion of the electrical line cross section is taken over by the solder or the conductive tape arrangement during operation of the solar cell 1, with the result that the emitter connection structure 6 itself does not need to be a low-resistance electrical conductor.

In the exemplary embodiment illustrated, the emitter connection structure 6 is a 150 nm thin nickel layer. In this case, the emitter connection structure 6 is not restricted to such a layer thickness, however. In other embodiments of the present invention which are not shown, the layer thickness of the emitter connection structure 6 can be between 100 nm and 150 nm or else between 50 nm and 500 nm or else generally below 5 μm. In principle, however, layer thicknesses of above 5 μm are also usable for the emitter connection structure 6 in accordance with the invention. The soldering of copper tapes in the same soldering installations, so-called stringers, in which tape arrangements can also be soldered onto standard solar cells from the prior art having busbars consisting of silver is possible on the nickel layer used in FIG. 1.

The base contact structure 7, which is a large-area aluminum layer in the exemplary embodiment illustrated, is located on the backside of the solar cell 1. A solderable metallic base connection structure 8 is applied to the outer side of the base contact structure 7. In the exemplary embodiment shown, the base connection structure 8 is in the form of three busbars consisting of nickel. In this case, too, the three busbars illustrated are merely used for demonstrative purposes, with any number of busbars for forming the base connection structure 8 generally being possible. In other variant embodiments of the present invention which are not shown, tin, a nickel alloy or a tin alloy can also be used for the production of the base connection structure 8. In principle, other materials are also usable for the production of the base connection structure 8.

In the exemplary embodiment shown in FIG. 1, the emitter connection structure 6 and the base connection structure 8 are formed opposite one another in each case by sputtering of nickel via sputtering masks. In another exemplary embodiment (not illustrated), the base connection structure 8 can also be deposited over the entire area, for example, as a tin alloy layer.

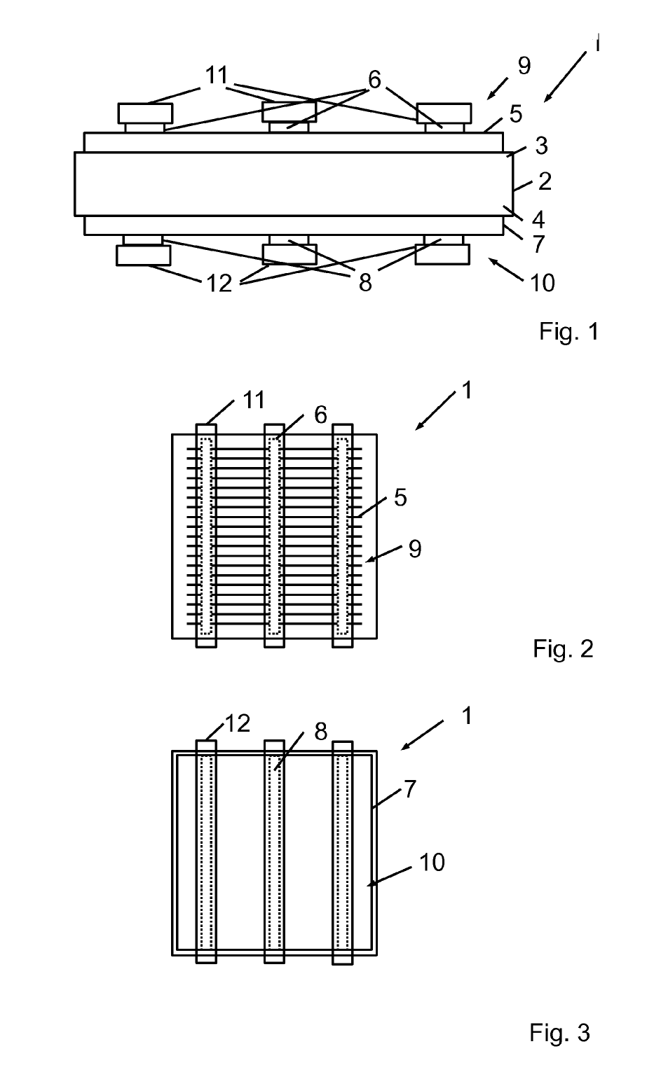

FIG. 2 shows, schematically, the embodiment of the solar cell 1 according to the invention shown in FIG. 1 in a plan view of the front side 9 of the solar cell 1. In this case, identical elements have been denoted by the same reference symbols as in FIG. 1. It is clear in this view that the emitter connection structure 6 occupies a large area in comparison with the emitter contact structure 5, which would be associated with correspondingly high costs in the case of a development of the emitter contact structure 5 consisting of silver. In the solar cell 1 according to the invention, however, the emitter connection structure 6 is formed from inexpensive metals, with the result that the solar cell 1 according to the invention can be produced at less cost than a solar cell in which both the emitter contact structure and the emitter connection structure are produced from an expensive material such as silver, for example.

FIG. 3 shows, schematically, the exemplary embodiment of the solar cell 1 according to the invention shown in FIGS. 1 and 2 in a plan view of the backside 10 of the solar cell 1. The base contact structure 7 is applied in this case virtually over the entire area to the backside of the solar cell 1. The base connection structure 8, on the other hand, is formed locally in three strips, which are opposite the strips of the emitter connection structure 6. In the exemplary embodiment illustrated, the base connection structure 8 is produced by sputtering by means of a sputtering mask. In other method variants, the strips can also be deposited electrochemically or in another way by special linear plasma sources, by point deposition sources, which are moved relative to the solar cell.

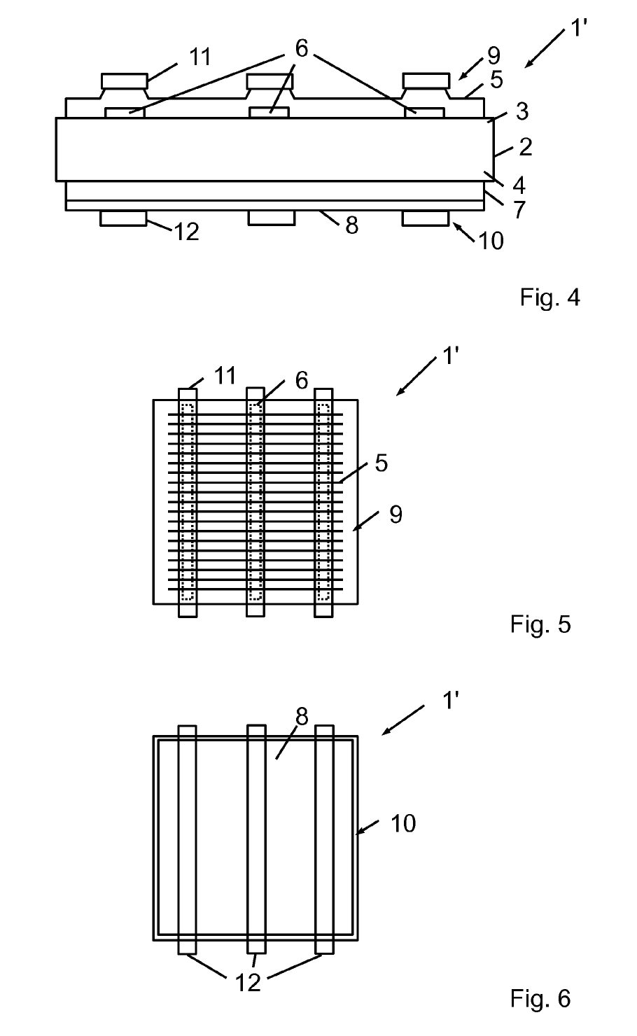

FIGS. 4, 5 and 6 illustrate, schematically, an embodiment of an alternative solar cell 1′ according to the invention. In this case, FIG. 4 shows a cross section through the solar cell 1′, FIG. 5 shows, schematically, a view of the front side 9 of the solar cell 1′, and FIG. 6 shows a plan view of the backside 10 of the solar cell 1′. In the exemplary embodiment shown, the solar cell core 2 is a heterojunction solar cell, in which the base 4 and the emitter 3 consist of different materials. In the exemplary embodiment illustrated, the base 4 is a crystalline silicon wafer, on which the emitter 3 is deposited as gradient layer. In this case, an electrically conductive, transparent oxide layer (not illustrated here, however) which is located on the emitter 3 and is used as antireflection and connection layer also belongs to the solar cell core 2. In this exemplary embodiment, first the emitter connection structure 6 is produced by physical gas phase deposition on the front side 9 of the solar cell core 2. Then, the emitter contact structure 5 is produced by screenprinting with a silver-polymer paste and subsequent temperature treatment at 300° C. A base contact structure 7 substantially over the entire area consisting of an aluminum layer is formed on the backside 10 of the solar cell 1′, and then the solderable metallic base connection structure 8 is formed likewise as a layer over the entire area.

The exemplary embodiments illustrated serve merely to illustrate and explain the invention. In no way do they represent a restriction of the invention to these exemplary embodiments. A person skilled in the field of the invention will know, however, on the basis of his knowledge in the art that the invention can be realized also in modified form using the present description.

It is easily possible to derive the method used according to the invention for producing the solar cells 1, 1′ from the exemplary embodiments illustrated in FIGS. 1 to 6. In this method, first a solar cell core 2 is produced or is made available, in which solar cell core, in the event of the incidence of light into the front side 9 of the solar cell 1, 1′, charge separation and charge transfer to the emitter 3 and to the base 4, which is located on that side 10 of the solar cell 1, 1′ which is opposite to the emitter 3, are provided.

Thereupon, the electrically conductive emitter contact structure 5, which is in direct electrical contact with the emitter 3, is produced. Parallel to this, the base contact structure 7 can also be produced.

Either after or even as early as before the production of the emitter contact structure 5, the solderable metallic emitter connection structure 6 is produced, which is in direct electrical contact with the emitter contact structure 5. Parallel to this or else in a separate step, the base connection structure 8 can be produced on the opposite side of the solar cell 1, 1′.

In order to produce the emitter connection structure 6, nickel, a nickel alloy, tin and/or a tin alloy is used. It is favorable also if nickel, a nickel alloy, tin and/or a tin alloy is used for the production of the base connection structure 8.

The emitter connection structure 6 is preferably formed with a relatively small layer thickness. Thus, in one variant embodiment of the method according to the invention, for example, only 100 to 150 nm thick nickel or nickel vanadium layers can be used as a replacement for the silver busbars used in the prior art as emitter connection structure 6.

In accordance with the invention, the emitter connection structure 6 or the busbars on the silicon solar cells produced is/are required in the further-processing of the cells to form modules for the cell interconnection, i.e., in the so-called stringing, in the module process. It is worth mentioning here that, despite the modifications performed in accordance with the invention in the production method of the solar cell 1, 1′ according to the invention, there are not necessarily any modifications in the rest of the process sequence to the finished module, as is the case in other technologies known from the prior art which likewise bring about lower costs for silver pastes. Furthermore, it is possible to work with standard cell connectors, standard solders and standard module equipment, in particular in the case of the stringer used.

The thin nickel layer which can be used, for example, for producing the emitter connection structure 6 can be deposited, for example, by means of vacuum deposition, such as sputtering deposition. The rate of solubility of nickel in standard solder material is much less than that of silver, which provides the possibility of working with the above-mentioned low layer thicknesses during production of the emitter connection structure 6.

In order to achieve corresponding structuring of the emitter connection structure 6 as early as during the deposition, it is recommended to use a shadow mask in the deposition of the layer used in each case for the emitter connection structure 6, wherein those regions in which the busbars (emitter connection structure 6) are intended to be produced are exposed and correspondingly coated.

The backside 10 of the solar cell 1, 1′ can, as already mentioned above, either be coated over the entire area in order to produce the base connection structure 8 or can likewise be formed using a shadow mask only in specific positions of the busbars (base connection structure 8) to be produced.

The respectively used sputter coating can be performed in a process step by parallel coating from above and below. Preferably, equipping the respectively used sputter coating installation with solar cell wafers using substrate carriers into which the solar cells and their shadow masks are inserted takes place. In this case, care should be taken to ensure a termination of the shadow mask and the solar cell which is as flush as possible in order that a sharp edge is produced and, where possible, no back-sputtering arises in the active region of the solar cell.

In a subsequent method step, the nickel layer strips forming the emitter connection structure 6 are provided, for example, by means of the electrically conductive tape arrangement 11 covered with solder and are soldered thereto. The solderability of the thin nickel layers in the stringing process is typically good. Similar withdrawal forces to those in the case of pure silver busbars, i.e. >2 N, are achieved.

The process flow used in accordance with the invention is configured as follows when using backside-passivated standard solar cells (passivated emitter and rear contacts (PERC) structure):

screenprinting of the emitter and base contact structures 5, 7 in the form of contact fingers; alternative embodiment of contact finger structures interrupted at the busbar positions

firing of the contact finger structures

deposition of the emitter and base connection structures 6, 8 by means of shadow masks on the front side and backside 9, 10 of the solar cell in the vacuum process

final measurement at the flasher, with preferably the measurement pins which are normally positioned onto the busbars needing to be replaced by a measurement strip on the measurement table of the flasher.

In the production of heterojunction solar cells, the following process flow results in accordance with the invention:

coating of the solar cell core 2 with a transparent, electrically conductive oxide (TCO) using the sputtering method

discharge

positioning of a shadow mask

coating with NiV on the front side and backside 9, 10 of the solar cell so as to form the emitter connection structure 6 and the base connection structure 8 (the coating with NiV can be performed in the same installation as the TCO coating; however, a specially configured PVD installation for coating on both sides using a shadow mask can also be used)

printing of the emitter contact structure 5 so as to form silver contact fingers on the solar cell front side 9 (possibly with cutout via the nickel busbar)

drying of the silver paste

final measurement at the flasher.

Although in the above-described exemplary method variants it has essentially been assumed that the nickel layers used, for example, for producing the emitter and base connection structures 6, 8 are produced using a PVD method, it is also quite conceivable to produce these layers by means of a screenprinting method. For this, however, corresponding pastes are required. Although printed layers are generally thicker than sputtered layers, this can be accepted with respect to the production costs for the solar cell since the materials proposed in accordance with the invention, such as nickel, tin, nickel alloys or tin alloys, are much less expensive than the silver used in the prior art.

By virtue of the solar cell 1, 1′ proposed in accordance with the invention and the method according to the invention correspondingly proposed, 50 to 80% of the silver paste otherwise used can be saved in the solar cell production process of standard (PERC) solar cells. A particularly significant saving results when the method according to the invention is used for producing heterojunction solar cells. In this case, more than 50% of the very expensive polymer silver paste can be saved.

The method according to the invention furthermore results in a marked improvement in the front side soldering of heterojunction solar cells with an efficient and inexpensive standard cell connection process, which has until now not been possible in such a form in the prior art. The method according to the invention is furthermore characterized by the fact that it is completely compatible with standard module production methods. Thus, for example, the soldering can be performed using a conventional stringer. Modification of the equipment in the module sector is not necessary when applying the method according to the invention, and the standard equipment can still be used without any changes.

Despite the above-mentioned drastic possibilities for savings when using the method according to the invention, the quality of the cell connection in accordance with the invention is comparable with standard soldering techniques. Withdrawal forces of >2 N result. In addition, there are no losses of back surface field or the passivated backside owing to the backside busbars with the solar cells 1, 1′ according to the invention, which can result in increased efficiency of approximately 0.1 to 0.2% in comparison with the prior art in the case of the solar cells 1, 1′ produced in accordance with the invention.

1-25. (canceled)

26. A method for producing a solar cell, the method comprising:
producing a solar cell core, configured such that, in the event of incidence of light into a front side of the solar cell, charge separation and charge transfer to an emitter and to a base that is located on a side of the solar cell opposite the emitter are provided;
producing an electrically conductive emitter contact structure in the form of contact fingers, that are in direct electrical contact with the emitter;
producing a solderable metallic emitter connection structure in the form of busbars that are in direct electrical contact with the emitter contact structure and cross-connect the contact fingers of the emitter contact structure, wherein contact is made with the emitter and the base on opposite sides of the solar cell and wherein the solderable metallic emitter connection structure is produced at least from nickel, a nickel alloy, tin and/or a tin alloy; and
applying a solder or an electrically conductive tape arrangement covered with solder to the emitter connection structure.

27. The method as claimed in claim 26, further comprising:
producing a base contact structure that is in direct electrical contact with the base;
producing a solderable metallic base connection structure that is in direct electrical contact with the base contact structure, the base connection structure produced at least from nickel, a nickel alloy, tin and/or a tin alloy; and
applying a solder or an electrically conductive tape arrangement covered with a solder to the base connection structure.

28. The method as claimed in claim 27, wherein the emitter connection structure and/or the base connection structure is/are produced with a layer thickness of below 5 μm.

29. The method as claimed in claim 28, wherein the emitter connection structure and/or the base connection structure is/are produced with a layer thickness of between 50 nm and 500 nm.

30. The method as claimed in claim 29, wherein the emitter connection structure and/or the base connection structure is/are produced with a layer thickness of between 100 nm and 150 nm.

31. The method as claimed in claim 27, wherein the emitter contact structure and/or the base contact structure is/are produced from a metal paste and/or from an electrolytic bath.

32. The method as claimed in claim 27, wherein the emitter contact structure and/or the base contact structure is/are formed with a layer thickness of between 5 μm and 50 μm.

33. The method as claimed in claim 26, wherein the emitter contact structure is produced from a silver paste.

34. The method as claimed in claim 27, wherein the emitter connection structure and/or the base connection structure is/are produced by locally performed layer deposition.

35. The method as claimed in claim 34, wherein the emitter connection structure and/or the base connection structure is/are deposited using a shadow mask during a physical vacuum deposition method.

36. The method as claimed in claim 27, wherein the emitter connection structure and the base connection structure are produced simultaneously in one method step.

37. The method as claimed in claim 27, wherein the emitter contact structure and/or the base contact structure is/are produced in at least one method step initially using screenprinting of a metal paste, and the emitter connection structure and/or the base connection structure is/are produced in a subsequent method step.

38. The method as claimed in claim 27, wherein the emitter connection structure and/or the base connection structure is/are produced first in at least one method step, and the emitter contact structure and/or the base contact structure is/are produced in a subsequent method step.

39. The method as claimed in claim 38, wherein the emitter contact structure and/or the base contact structure is/are screenprinted with a metal-polymer paste, and then a temperature treatment at temperatures below 300° C. is performed in order to convert the metal-polymer paste into at least one metal layer.

40. The method as claimed in claim 27, wherein, in at least one method step, the solder is applied to the emitter connection structure and/or the base connection structure with a layer thickness of at least 20 μm or a copper tape arrangement is soldered onto the emitter connection structure and/or the base connection structure.

41. A solar cell, comprising:
a solar cell core, in which, in the event of incidence of light into a front side of the solar cell, charge separation and charge transfer to an emitter and to a base located on a side of the solar cell opposite the emitter are provided;
an electrically conductive emitter contact structure in the form of contact fingers that are in direct electrical contact with the emitter, wherein contact is made with the emitter and the base on opposite sides of the solar cell;
a solderable metallic emitter connection structure in the form of busbars that are in direct electrical contact with the emitter contact structure and cross-connect the contact fingers of the emitter contact structure, wherein the solderable metallic emitter connection structure is formed at least from nickel, a nickel alloy, tin and/or a tin alloy; and
a solder or an electrically conductive tape arrangement covered with solder disposed on the solderable metallic emitter connection structure.

42. The solar cell as claimed in claim 41, further comprising a base contact structure in direct electrical contact with the base, and a solderable metallic base connection structure in direct electrical contact with the base contact structure, wherein the base connection structure is formed at least from nickel, a nickel alloy, tin and/or a tin alloy, and wherein a solder or an electrically conductive tape arrangement covered with a solder is provided on the solderable metallic base connection structure.

43. The solar cell as claimed in claim 42, wherein the emitter connection structure and/or the base connection structure has/have a layer thickness of below 5 μm.

44. The solar cell as claimed in claim 43, wherein the emitter connection structure and/or the base connection structure has/have a layer thickness of between 50 nm and 500 nm.

45. The solar cell as claimed in claim 44, wherein the emitter connection structure and/or the base connection structure has/have a layer thickness of between 100 nm and 150 nm.

46. The solar cell as claimed in claim 42, wherein the emitter connection structure and/or the base connection structure is/are formed from a metal paste and/or an electrolytically deposited material.

47. The solar cell as claimed in claim 42, wherein the emitter connection structure and/or the base connection structure has/have a layer thickness of between 5 μm and 20 μm.

48. The solar cell as claimed in claim 42, wherein the emitter connection structure and/or the base connection structure has/have contact fingers formed from a silver paste.

49. The solar cell as claimed in claim 42, wherein the emitter contact structure is provided between the solar cell core and the emitter connection structure and/or the base contact structure is provided between the solar cell core and the base connection structure.

50. The solar cell as claimed in claim 42, wherein the emitter connection structure is provided between the solar cell core and the emitter contact structure and/or the base connection structure is provided between the solar cell core and the base contact structure.
